(19) United States
(12) Patent Application Publication
(10) Pub. No.: US 2019/0326249 A1
(43) Pub. Date: Oct. 24, 2019

(54) MULTI-POINT STACKED DIE WIREBONDING FOR IMPROVED POWER DELIVERY

(71) Applicant: Intel Corporation, Santa Clara, CA (US)

(72) Inventors: John G. Meyers, Sacramento, CA (US); Florence R. Pon, Folsom, CA (US)

(73) Assignee: Intel Corporation, Santa Clara, CA (US)

(21) Appl. No.: 16/465,046

(22) PCT Filed: Dec. 29, 2016
(86) PCT No.: PCT/US2016/069311

§ 371 Date: May 29, 2019

(51) Int. Cl. H01L 23/00; G11C 5/06; H01L 25/065; H01L 21/56; H01L 23/31

(52) U.S. Cl. CPC H01L 24/49; G11C 5/06; H01L 25/0657; H01L 24/09; H01L 21/563; H01L 23/3107; H01L 21/565

(57) ABSTRACT

An apparatus is provided which comprises: a plurality of circuit regions in an integrated circuit die, wherein the circuit regions comprise circuit components formed in semiconductor material, a plurality of interconnect regions to route power to the circuit regions from a surface of the integrated circuit die, wherein the interconnect regions comprise conductive traces within dielectric material and a plurality of wirebond pads on the surface of the integrated circuit die, wherein the wirebond pads comprise a substantially even distribution over the surface of the integrated circuit die. Other embodiments are also disclosed and claimed.

### BACKGROUND

Certain integrated circuit devices, such as memory silicon devices, for example, may have relatively high power requirements. Additionally, the need to include more computing power and storage in device packages has led to more solutions where dies are stacked on top of other dies. With stacking it is difficult to meet the power requirements of all dies in a stack using through silicon vias. Wirebonding to bond pads near sides of a top surface of a stacked die has been used conventionally, however as power requirements continue to increase, these prior solutions might not be able to provide sufficient power to all areas of a die.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a cross-sectional view of a package with multi-point stacked die wirebonding, according to some embodiments,

FIG. 2 illustrates an isometric view of an integrated circuit die suitable for a package with multi-point stacked die wirebonding, according to some embodiments,

FIGS. 3A-3F illustrate cross-sectional views of manufacturing steps of a package with multi-point stacked die wirebonding, according to some embodiments,

FIG. 4 illustrates a flowchart of a method of forming a package with multi-point stacked die wirebonding, in accordance with some embodiments, and

FIG. 5 illustrates a smart device or a computer system or a SoC (System-on-Chip) which includes a package with multi-point stacked die wirebonding, according to some embodiments.

### DETAILED DESCRIPTION

Multi-point stacked die wirebonding for improved power delivery is generally presented. In this regard, embodiments of the present invention enable power to be delivered via bonding wire to virtually any area of a die surface. One skilled in the art would appreciate that delivery of power to distributed pads across a die surface through relatively low-resistant bonding wire may reduce the length of power routing needed within the die, thereby potentially lowering resistance and improving power delivery. Additionally, embodiments of the present invention may enable package substrates to be made smaller as wirebonding may not be necessary around all sides of a die, since multiple pads on a die surface can be wirebonded together and routed over a single side of the die.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left,” “right,” “front,” “back,” “top,” “bottom,” “over,” “under,” and the like in the description and in the claims, if any, are used for descriptive purposes and not necessarily for describing permanent relative positions.

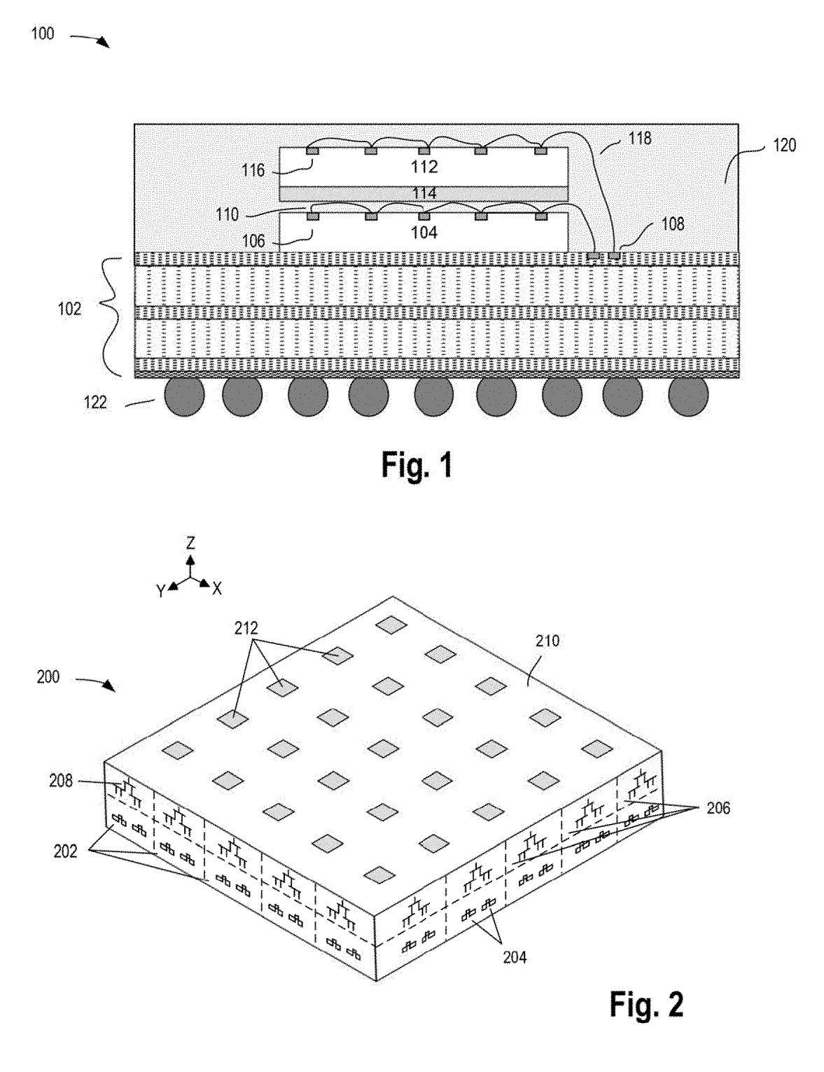

FIG. 1 illustrates a cross-sectional view of a package with multi-point stacked die wirebonding, according to some embodiments. As shown, package 100 includes substrate 102, first die 104, first die bond pads 106, substrate surface bond pads 108, first die bond wire 110, second die 112, insulative film 114, second die bond pads 116, second die bond wire 118, mold 120, and package contacts 122.

While shown as including a first die 104 and a second die 112, package 100 can include any number of dies of similar or different types of integrated circuit devices. For example, die 104 and/or die 112 can be any of application processors, graphics processors, field programmable gate arrays (FPGA), input/output (I/O) controllers, network controllers, or memory devices, among other devices. Substrate 102 may comprise a plurality of dielectric layers with vertical and horizontal copper, or other conductive material, disposed therein. Substrate 102 may include vias, planes and traces (not show) to conductively couple substrate surface bond pads 108 with package contacts 122. Package contacts 122 may enable package 100 to be coupled with a printed circuit board and may include ball grid array (BGA) or land grid array (LGA) contacts, for example.

First die 104 may receive power delivery through wirebonding of first die bond pads 106 with substrate surface bond pads 108 of substrate 102. First die 104 and second die 112 may include bond pads that are substantially evenly distributed across a surface of the dies. In some embodiments, first die 104 and second die 112 may have a layout of bond pads similar to that of die 200 shown in FIG. 2 hereinafter. First die bond pads 106 may represent a row of bond pads that are wirebonded (with first die bond wire 110) together with a single contiguous wire or with separate wire segments. In some embodiments, series of first die bond pads 106, being conductively couple among each other, can receive power through a single wire bonded to a surface bond pad 108. In some embodiments, additional rows of first die bond pads 106 may similarly be wirebonded together and to a single surface bond pad 108 on the same side of first die 104 as shown.

Second die 112 may be placed over first die bond wire 110, with insulative film 114 separating them. In some embodiments, insulative film 114 provides adhesion as well as electrical insulation. In some embodiments, second die 112 is similarly wirebond as first die 104, with groupings of second die bond pads 116 conductively coupled together and with substrate surface bond pads 108. In some embodiments, second die bond wire 118 is routed over a same side of second die 112 as first die bond wire 110 is routed over first die 104.

Mold 120 may encapsulate first die 104, first die bond wire 110, second die 112 and second die bond wire 118, for example. In some embodiments, mold 120 may be dispensed in a liquid state that allows it to substantially fill any space between insulative film 114 and first die 104, surrounding first die bond wire 110. Mold 120 may include epoxy or other dielectric material.

FIG. 2 illustrates an isometric view of an integrated circuit die suitable for a package with multi-point stacked die wirebonding, according to some embodiments. As shown, integrated circuit die 200 includes circuit regions 202, circuit components 204, interconnect regions 206, interconnects 208, die surface 210 and bond pads 212.

In some embodiments, integrated circuit die 200 may be spliced from a semiconductor wafer that has undergone extensive processing steps. While shown as containing a plurality of circuit regions 202 and interconnect regions 206, in some embodiments, these regions may not be visibly or logically separate portions of integrated circuit die 200, but rather may be abstractions that serve to aid in understanding of embodiments of the present invention. In some embodiments, there is a one to one to one correspondence between each bond pad 212, circuit region 202, and interconnect region 206, however, not every circuit region 202 and interconnect region 206 need be identical with every other circuit region 202 and interconnect region 206.

In some embodiments, circuit regions 202 include many thousands of circuit components 204. In some embodiments, circuit components 204 may include semiconductor switches, transistors, memory cells or other components. In some embodiments, circuit regions 202 contain semiconductor material, such as silicon, germanium, etc.

In some embodiments, interconnect regions 206 contain a plurality of interconnects 208 to, for example, route power from bond pads 212 on die surface 210 above interconnect regions 206 to circuit regions 202 below interconnect regions 206. In some embodiments, interconnect regions 206 are designed to minimize the length of interconnects 208 in order to reduce effective resistance.

Bond pads 212 may be distributed substantially evenly over die surface 210. Bond pads 212 may contain metal plating to facilitate wirebonding, for example by soldering. In some embodiments, bond pads 212 may be arranged in two dimensional rows and columns. In some embodiments, bond pads 212 may be present with substantially consistent spacing along the x-axis and/or the y-axis. While shown as being arranged linearly, bond pads 212 may be staggered, irregularly spaced or otherwise less organized in appearance.

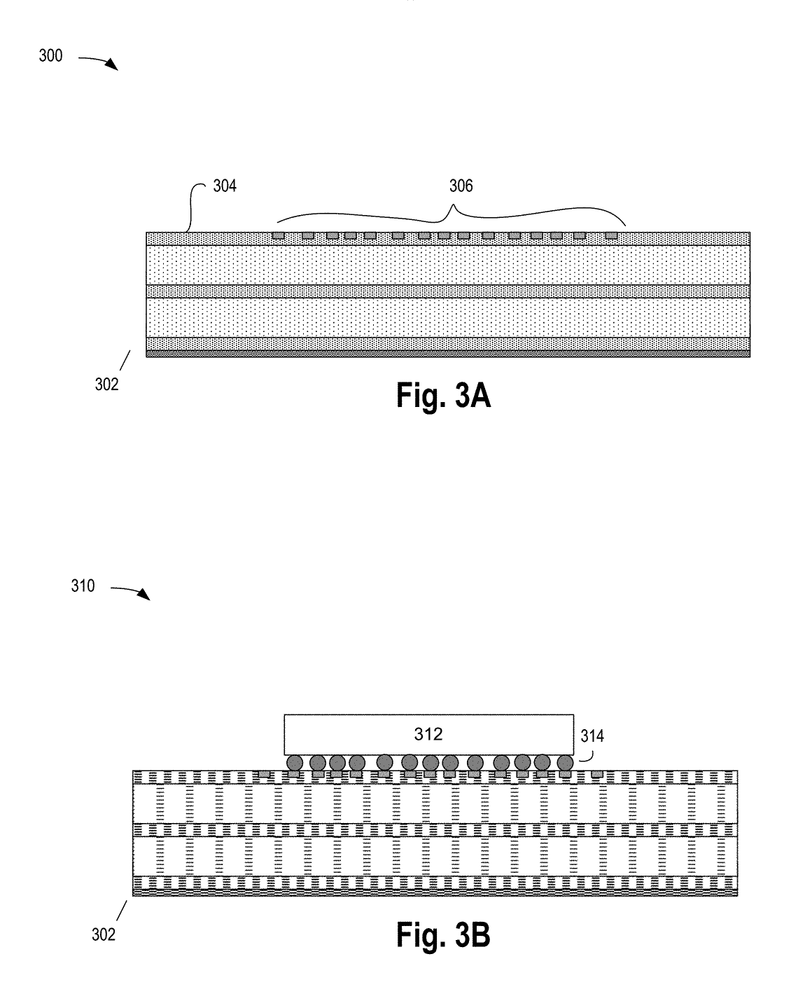

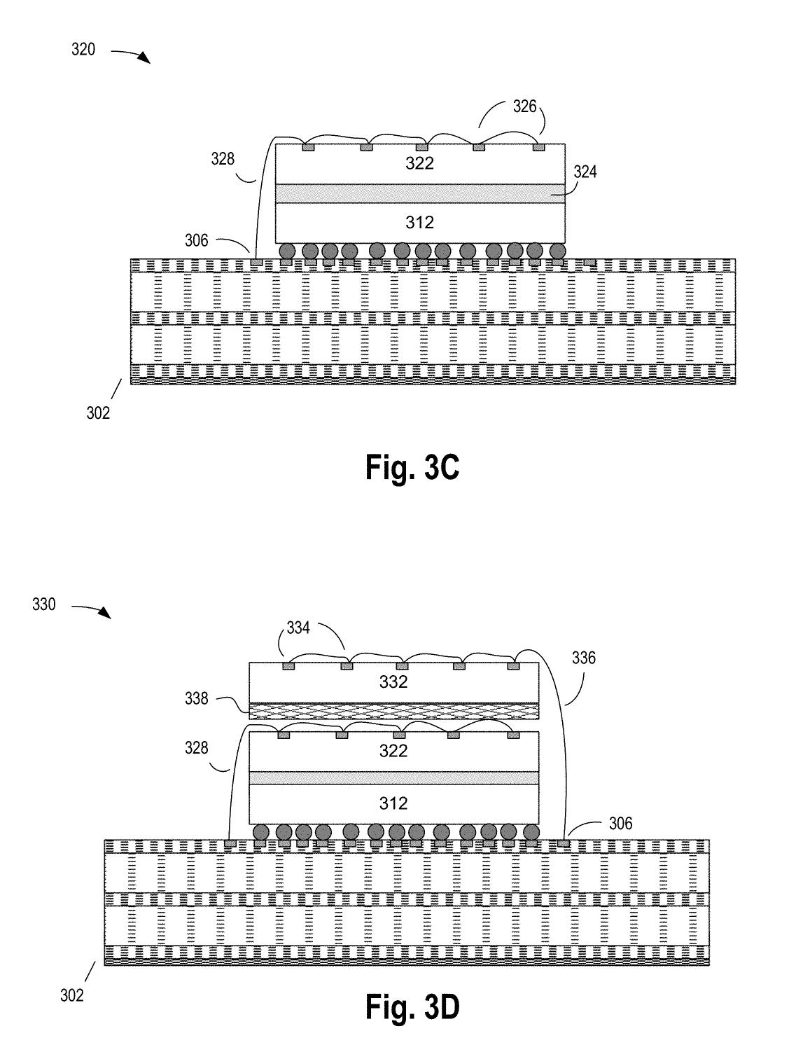

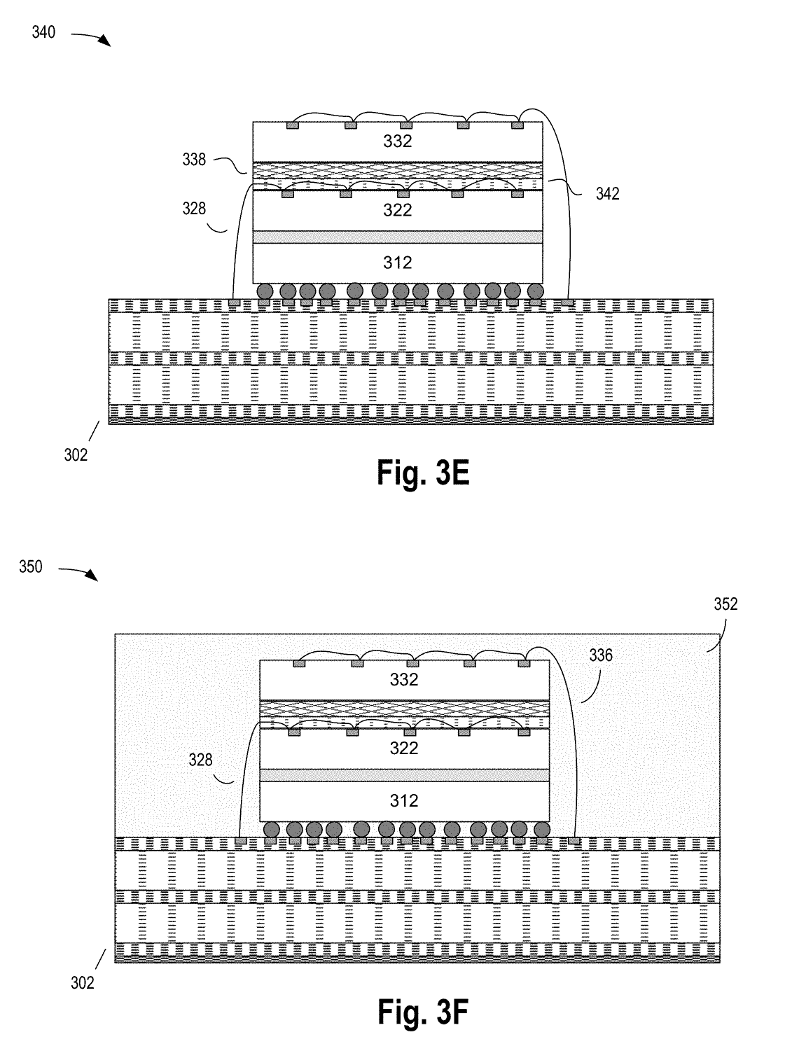

FIGS. 3A-3F illustrate cross-sectional views of manufacturing steps of a package with multi-point stacked die wirebonding, according to some embodiments. As shown in FIG. 3A, assembly 300 includes substrate 302, substrate surface 304 and substrate pads 306. Substrate 302 may represent any type of substrate for receiving an integrated circuit device, including, but not limited to, a metal core or coreless dielectric or fiberglass based substrate. In some embodiments, substrate pads 306 may represent metal plated pads connecting to underlying conductive traces (not shown) to communicatively and/or electrically couple computing components. In some embodiments, substrate pads 306 may be able to bond with solder balls, bondwire, or other solder-based attachments

FIG. 3B shows assembly 310, which may have had flip chip die 312 coupled to substrate surface 304. In some embodiments, flip chip die 312 includes solder balls 314 for coupling with some of substrate pads 306. In some embodiments, flip chip die 312 may represent a processor, controller, FPGA, or other type of integrated circuit device.

As shown in FIG. 3C, assembly 320 may include die 322, adhesive 324, die bond pads 326, and bond wire 328. In some embodiments, die 322 is attached to flip chip die 312 with adhesive 324. In some embodiments, bond wire 328 may couple a grouping of die bond pads 326 with each other and with a substrate pad 306. In some embodiments, die 322 may have a distribution of die bond pads 326 similar to integrated circuit die 200 described above in relation to FIG. 2.

Turning now to FIG. 3D, assembly 330 may include die 332, die bond pads 334, bond wire 336 and insulative film 338. Insulative film 338 may insulate bond wire 328 from die 332. In some embodiments, bond wire 336 may couple die bond pads 334 with each other and with a substrate pad 306. In some embodiments, die 332 may have a distribution of die bond pads 334 similar to integrated circuit die 200 described above in relation to FIG. 2.

FIG. 3E shows assembly 340, which may include underfill 342. In some embodiments, underfill 342 is a capillary underfill that fills in the space between insulative film 338 and die 322. In some embodiments, underfill 342 surrounds bondwire 328, which may have been partially compressed by contact from insulative film 338.

As shown in FIG. 3F, for assembly 350, mold 352 may encapsulate components above substrate surface 304, including die 332 and bond wire 336. In some embodiments, mold 352 is an air-cured epoxy, though other mold 352 materials may be used.

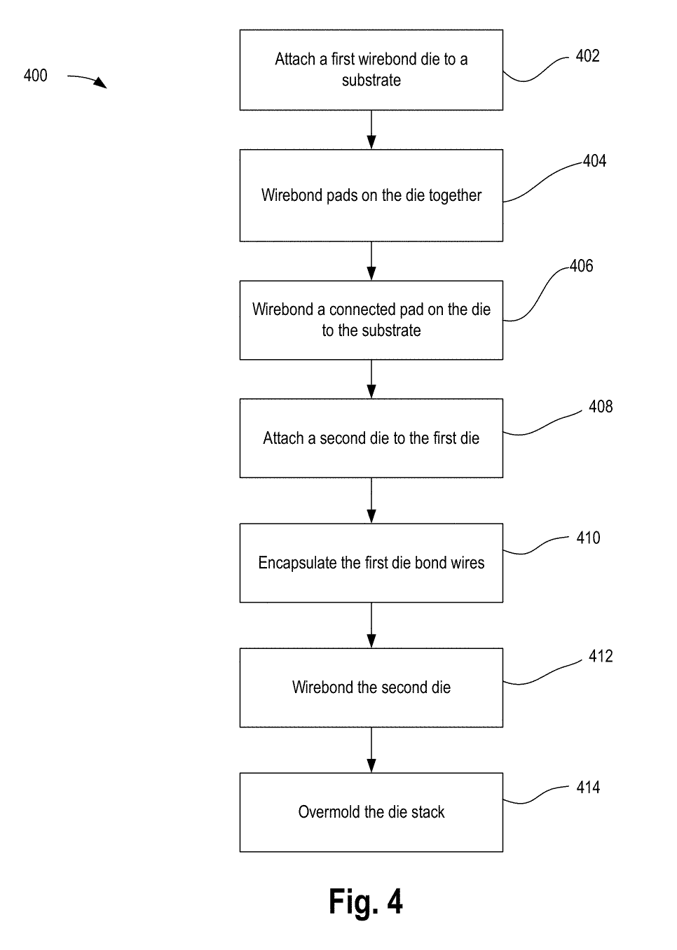

FIG. 4 illustrates a flowchart of a method of forming a package with multi-point stacked die wirebonding, in accordance with some embodiments. Although the blocks in the flowchart with reference to FIG. 4 are shown in a particular order, the order of the actions can be modified. Thus, the illustrated embodiments can be performed in a different order, and some actions/blocks may be performed in parallel. Some of the blocks and/or operations listed in FIG. 4 are optional in accordance with certain embodiments. The numbering of the blocks presented is for the sake of clarity and is not intended to prescribe an order of operations in which the various blocks must occur. Additionally, operations from the various flows may be utilized in a variety of combinations.

Method 400 begins with attaching (402) a first wirebond die (such as die 322, for example) to a substrate. In some embodiments, the first wirebond die may be adhered to a flip chip die. In other embodiments, the first wirebond die may be adhered directly to a surface of a substrate. Next, pads on the die are wirebonded (404) together. In some embodiments, a row of pads may be wirebonded to one another with a single wire that is bent and soldered to subsequent pads.

Then, a connected pad may be wirebonded (406) to a pad on a substrate surface. In some embodiments, an outermost pad, closest to a side of the die, among a row of pads on a die surface is utilized as a connection point for the bonding wire that is bonded to a pad on the substrate surface. Next, in some embodiments, an additional wirebond die is attached (408) to the first wirebond die. In some embodiments, the second wirebond die is placed over wirebonds on the surface of the first wirebond die, with an insulative film between them.

The method continues with encapsulating (410) the bond wires above the first wirebond die. In some embodiments, an underfill material is flowed into the space between the dies to encapsulate the bond wires. In other embodiments, an insulative film may also serve as an encapsulant. Next, the second die is wirebonded (412) to a substrate and amongst groupings of bond pads on the second die. In some embodiments, the second wirebond die includes bond wires that extend over a same die side as wires bonding the first wirebond die. Finally, the die stack may be overmolded (414) to encapsulate the dies and bond wires.

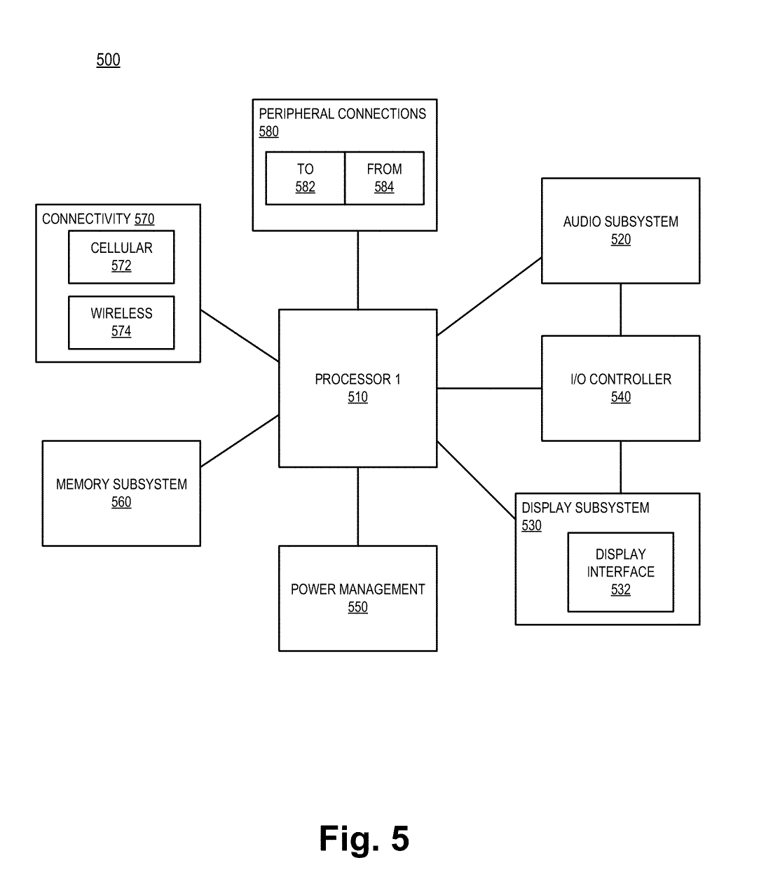

FIG. 5 illustrates a smart device or a computer system or a SoC (System-on-Chip) 500 which includes a package with multi-point stacked die wirebonding, according to some embodiments. In some embodiments, computing device 500 represents a mobile computing device, such as a computing tablet, a mobile phone or smart-phone, a wireless-enabled e-reader, or other wireless mobile device. It will be understood that certain components are shown generally, and not all components of such a device are shown in computing device 500. In some embodiments, one or more components of computing device 500, for example processor 510 and/or memory subsystem 560, are included in a package with multi-point stacked die wirebonding as described above.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, etc., may be used without departing from the scope of the disclosure.

In some embodiments, computing device 500 includes a first processor 510. The various embodiments of the present disclosure may also comprise a network interface within 570 such as a wireless interface so that a system embodiment may be incorporated into a wireless device, for example, cell phone or personal digital assistant.

In one embodiment, processor 510 can include one or more physical devices, such as microprocessors, application processors, microcontrollers, programmable logic devices, or other processing means. The processing operations performed by processor 510 include the execution of an operating platform or operating system on which applications and/or device functions are executed. The processing operations include operations related to I/O (input/output) with a human user or with other devices, operations related to power management, and/or operations related to connecting the computing device 500 to another device. The processing operations may also include operations related to audio I/O and/or display I/O.

In one embodiment, computing device 500 includes audio subsystem 520, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 500, or connected to the computing device 500. In one embodiment, a user interacts with the computing device 500 by providing audio commands that are received and processed by processor 510.

Display subsystem 530 represents hardware (e.g., display devices) and software (e.g., drivers) components that provide a visual and/or tactile display for a user to interact with the computing device 500. Display subsystem 530 includes display interface 532, which includes the particular screen or hardware device used to provide a display to a user. In one embodiment, display interface 532 includes logic separate from processor 510 to perform at least some processing related to the display. In one embodiment, display subsystem 530 includes a touch screen (or touch pad) device that provides both output and input to a user.

I/O controller 540 represents hardware devices and software components related to interaction with a user. I/O controller 540 is operable to manage hardware that is part of audio subsystem 520 and/or display subsystem 530. Additionally, I/O controller 540 illustrates a connection point for additional devices that connect to computing device 500 through which a user might interact with the system. For example, devices that can be attached to the computing device 500 might include microphone devices, speaker or stereo systems, video systems or other display devices, keyboard or keypad devices, or other I/O devices for use with specific applications such as card readers or other devices.

As mentioned above, I/O controller 540 can interact with audio subsystem 520 and/or display subsystem 530. For example, input through a microphone or other audio device can provide input or commands for one or more applications or functions of the computing device 500. Additionally, audio output can be provided instead of, or in addition to display output. In another example, if display subsystem 530 includes a touch screen, the display device also acts as an input device, which can be at least partially managed by I/O controller 540. There can also be additional buttons or switches on the computing device 500 to provide I/O functions managed by I/O controller 540.

In one embodiment, I/O controller 540 manages devices such as accelerometers, cameras, light sensors or other environmental sensors, or other hardware that can be included in the computing device 500. The input can be part of direct user interaction, as well as providing environmental input to the system to influence its operations (such as filtering for noise, adjusting displays for brightness detection, applying a flash for a camera, or other features).

In one embodiment, computing device 500 includes power management 550 that manages battery power usage, charging of the battery, and features related to power saving operation. Memory subsystem 560 includes memory devices for storing information in computing device 500. Memory can include nonvolatile (state does not change if power to the memory device is interrupted) and/or volatile (state is indeterminate if power to the memory device is interrupted) memory devices. Memory subsystem 560 can store application data, user data, music, photos, documents, or other data, as well as system data (whether long-term or temporary) related to the execution of the applications and functions of the computing device 500.

Elements of embodiments are also provided as a machine-readable medium (e.g., memory 560) for storing the computer-executable instructions. The machine-readable medium (e.g., memory 560) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 570 includes hardware devices (e.g., wireless and/or wired connectors and communication hardware) and software components (e.g., drivers, protocol stacks) to enable the computing device 500 to communicate with external devices. The computing device 500 could be separate devices, such as other computing devices, wireless access points or base stations, as well as peripherals such as headsets, printers, or other devices.

Connectivity 570 can include multiple different types of connectivity. To generalize, the computing device 500 is illustrated with cellular connectivity 572 and wireless connectivity 574. Cellular connectivity 572 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 574 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 580 include hardware interfaces and connectors, as well as software components (e.g., drivers, protocol stacks) to make peripheral connections. It will be understood that the computing device 500 could both be a peripheral device (“to” 582) to other computing devices, as well as have peripheral devices (“from” 584) connected to it. The computing device 500 commonly has a “docking” connector to connect to other computing devices for purposes such as managing (e.g., downloading and/or uploading, changing, synchronizing) content on computing device 500. Additionally, a docking connector can allow computing device 500 to connect to certain peripherals that allow the computing device 500 to control content output, for example, to audiovisual or other systems.

In addition to a proprietary docking connector or other proprietary connection hardware, the computing device 500 can make peripheral connections 580 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

In one example, an apparatus is provided comprising: a plurality of circuit regions in an integrated circuit die, wherein the circuit regions comprise circuit components formed in semiconductor material; a plurality of interconnect regions to route power to the circuit regions from a surface of the integrated circuit die, wherein the interconnect regions comprise conductive traces within a dielectric material; and a plurality of wirebond pads on the surface of the integrated circuit die, wherein the wirebond pads comprise a substantially even distribution over the surface of the integrated circuit die.

In some embodiments, the wirebond pads further comprise a substantially consistent spacing along a first axis. In some embodiments, the wirebond pads further comprise a substantially consistent spacing along a second axis. In some embodiments, the wirebond pads further comprise an arrangement in linear groupings along two dimensions. In some embodiments, the circuit regions comprise memory cells. Some embodiments also include one or more pair of adjacent wirebond pads bonded to each other with a wire.

In another example, an apparatus is provided comprising: a substrate, wherein the substrate comprises wirebond pads on a substrate surface; an integrated circuit die coupled to the substrate, wherein the integrated circuit die comprises two or more wirebond pads on a surface of the die, the wirebond pads disposed at disparate distances from a side of the surface of the die; and wire bonding the two or more wirebond pads on the surface of the die together, the wire further bonding an outermost of the two or more wirebond pads on the surface of the die to a wirebond pad on the surface of the substrate.

In some embodiments, the integrated circuit die coupled to the substrate comprises the integrated circuit die attached to a surface of a flip chip die coupled to the substrate. Some embodiments also include wire bonding any further wirebond pads on the surface of the die to wirebond pads on the surface of the substrate over the side of the surface of the die. In some embodiments, the wire bonding the two or more pads on the surface of the die together comprises separate wire segments. Some embodiments also include an additional integrated circuit die disposed over the surface of the first integrated circuit die. Some embodiments also include mold encapsulating the wire.

In another example, a system is provided comprising: a display subsystem; a wireless communication interface; and an integrated circuit package, the integrated circuit package comprising: a substrate, wherein the substrate comprises wirebond pads on a substrate surface; a first integrated circuit die coupled to the substrate surface, wherein the first integrated circuit die comprises two or more wirebond pads on a surface of the first die, the wirebond pads disposed at disparate distances from a side of the surface of the first die; wire bonding the two or more wirebond pads on the surface of the first die together, the wire further bonding an outermost of the two or more wirebond pads on the surface of the first die to a wirebond pad on the substrate surface; and a second integrated circuit die disposed over the surface of the first integrated circuit die, wherein the second integrated circuit die comprises two or more wirebond pads on a surface of the second die, the wirebond pads disposed at disparate distances from a side of the surface of the second die.

Some embodiments also include wire bonding any further wirebond pads on the surface of the first die to wirebond pads on the surface of the substrate over the side of the surface of the first die. Some embodiments also include wire bonding substantially all wirebond pads on the surface of the second die to wirebond pads on the surface of the substrate over the side of the surface of the second die, the side of the surface of the second die opposite of the side of the surface of the first die. Some embodiments also include an insulative film coupling the second integrated circuit die with the wire bonding the two or more wirebond pads on the surface of the first die. Some embodiments also include underfill material substantially filling a space between the first and second integrated circuit dies. Some embodiments also include mold encapsulating the wire, the first and the second integrated circuit dies.

In another example, a method is provided comprising: attaching an integrated circuit die to a substrate surface, wherein the integrated circuit die comprises a plurality of wirebond pads arranged in rows on a surface of the integrated circuit die; wirebonding a row of wirebond pads on the surface of the integrated circuit die to one another; and wirebonding a wirebond pad among the row of wirebond pads to a wirebond pad on the substrate surface.

In some embodiments, attaching the integrated circuit die comprises bonding the integrated circuit die to a flip chip die attached to the substrate surface. Some embodiments also include attaching a second integrated circuit die over the first integrated circuit die and wirebonding wirebond pads on a surface of the second integrated circuit die to one another. In some embodiments, attaching the second integrated circuit die over the first integrated circuit die comprises adhering a film on a surface of the second integrated circuit die to wire adjacent the surface of the first integrated circuit die.

In some embodiments, wirebonding a row of wirebond pads on the surface of the integrated circuit die to one another comprises bending and attaching a contiguous wire. Some embodiments also include wirebonding the first and second integrated circuit dies toward a same side of the substrate surface. Some embodiments also include dispensing a mold material to encapsulate the wire.

In another example, an integrated circuit device package with multi-point stacked die wirebonding is provided comprising: a substrate, wherein the substrate comprises bonding site means on a substrate surface; an integrated circuit means coupled to the substrate means, wherein the integrated circuit means comprises two or more bonding site means on a surface of the die, the bonding site means disposed at disparate distances from a side of the surface of the die; and bonding the two or more bonding site means on the surface of the die together with a bonding means, the bonding means further bonding an outermost of the two or more bonding site means on the surface of the die to a bonding site means on the surface of the substrate.

In some embodiments, the integrated circuit die coupled to the substrate comprises the integrated circuit die attached to a surface of a flip chip die coupled to the substrate. Some embodiments also include bonding any further bonding site means on the surface of the die to bonding site means on the surface of the substrate over the side of the surface of the die. In some embodiments, the bonding means bonding the two or more bonding site means on the surface of the die together comprises separate bonding means segments. Some embodiments also include an additional integrated circuit die disposed over the surface of the first integrated circuit die. Some embodiments also include encapsulating means surrounding the bonding means.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1-25. (canceled)

26. An apparatus comprising:
a plurality of circuit regions in an integrated circuit die, wherein the circuit regions comprise circuit components formed in semiconductor material;
a plurality of interconnect regions to route power to the circuit regions from a surface of the integrated circuit die, wherein the interconnect regions comprise conductive traces within a dielectric material; and
a plurality of wirebond pads on the surface of the integrated circuit die, wherein the wirebond pads comprise a substantially even distribution over the surface of the integrated circuit die.

27. The apparatus of claim 26, wherein the wirebond pads further comprise a substantially consistent spacing along a first axis.

28. The apparatus of claim 27, wherein the wirebond pads further comprise a substantially consistent spacing along a second axis.

29. The apparatus of claim 26, wherein the wirebond pads further comprise an arrangement in linear groupings along two dimensions.

30. The apparatus of claim 26, wherein the circuit regions comprise memory cells.

31. The apparatus of claim 26, further comprising one or more pair of adjacent wirebond pads bonded to each other with a wire.

32. An apparatus comprising:
a substrate, wherein the substrate comprises wirebond pads on a substrate surface;
an integrated circuit die coupled to the substrate, wherein the integrated circuit die comprises two or more wirebond pads on a surface of the die, the wirebond pads disposed at disparate distances from a side of the surface of the die; and
wire bonding the two or more wirebond pads on the surface of the die together, the wire further bonding an outermost of the two or more wirebond pads on the surface of the die to a wirebond pad on the surface of the substrate.

33. The apparatus of claim 32, wherein the integrated circuit die coupled to the substrate comprises the integrated circuit die attached to a surface of a flip chip die coupled to the substrate.

34. The apparatus of claim 32, further comprising wire bonding any further wirebond pads on the surface of the die to wirebond pads on the surface of the substrate over the side of the surface of the die.

35. The apparatus of claim 32, wherein the wire bonding the two or more pads on the surface of the die together comprises separate wire segments.

36. The apparatus of claim 32, further comprising an additional integrated circuit die disposed over the surface of the first integrated circuit die.

37. The apparatus of claim 32, further comprising mold encapsulating the wire.

38. A system comprising:
a display subsystem;
a wireless communication interface; and
an integrated circuit package, the integrated circuit package comprising:
a substrate, wherein the substrate comprises wirebond pads on a substrate surface;
a first integrated circuit die coupled to the substrate surface, wherein the first integrated circuit die comprises two or more wirebond pads on a surface of the first die, the wirebond pads disposed at disparate distances from a side of the surface of the first die;
wire bonding the two or more wirebond pads on the surface of the first die together, the wire further bonding an outermost of the two or more wirebond pads on the surface of the first die to a wirebond pad on the substrate surface; and
a second integrated circuit die disposed over the surface of the first integrated circuit die, wherein the second integrated circuit die comprises two or more wirebond pads on a surface of the second die, the wirebond pads disposed at disparate distances from a side of the surface of the second die.

39. The system of claim 38, further comprising wire bonding any further wirebond pads on the surface of the first die to wirebond pads on the surface of the substrate over the side of the surface of the first die.

40. The system of claim 39, further comprising wire bonding substantially all wirebond pads on the surface of the second die to wirebond pads on the surface of the substrate over the side of the surface of the second die, the side of the surface of the second die opposite of the side of the surface of the first die.

41. The system of claim 38, further comprising an insulative film coupling the second integrated circuit die with the wire bonding the two or more wirebond pads on the surface of the first die.

42. The system of claim 38, further comprising underfill material substantially filling a space between the first and second integrated circuit dies.

43. The system of claim 38, further comprising mold encapsulating the wire, the first and the second integrated circuit dies.

44. A method comprising:
attaching an integrated circuit die to a substrate surface, wherein the integrated circuit die comprises a plurality of wirebond pads arranged in rows on a surface of the integrated circuit die;
wirebonding a row of wirebond pads on the surface of the integrated circuit die to one another; and
wirebonding a wirebond pad among the row of wirebond pads to a wirebond pad on the substrate surface.

45. The method of claim 44, wherein attaching the integrated circuit die comprises bonding the integrated circuit die to a flip chip die attached to the substrate surface.

46. The method of claim 44, further comprising:
attaching a second integrated circuit die over the first integrated circuit die; and
wirebonding wirebond pads on a surface of the second integrated circuit die to one another.

47. The method of claim 46, wherein attaching the second integrated circuit die over the first integrated circuit die comprises adhering a film on a surface of the second integrated circuit die to wire adjacent the surface of the first integrated circuit die.

48. The method of claim 44, wherein wirebonding a row of wirebond pads on the surface of the integrated circuit die to one another comprises bending and attaching a contiguous wire.

49. The method of claim 48, further comprising wirebonding the first and second integrated circuit dies toward a same side of the substrate surface.

50. The method of claim 44, further comprising dispensing a mold material to encapsulate the wire.
